(19) United States
(12) Patent Application Publication
(10) Pub. No.: US 2006/0189119 A1
(43) Pub. Date: Aug. 24, 2006

(54) Encapsulation of circuit components to reduce thermal cycling stress

(76) Inventor: Michael Jin, Petaluma, CA (US)

Correspondence Address: SIDLEY AUSTIN BROWN & WOOD LLP (LAIP GROUP), 555 W. FIFTH ST., SUITE 4000, LOS ANGELES, CA, 90013, US

(21) Appl. No.: 11/338,338

(22) Filed: Jan. 24, 2006

Related U.S. Application Data
(60) Provisional application No. 60/646,801, filed on Jan. 24, 2005.

(51) Int. Cl. H01L 21/50; H01L 21/44; H01L 21/48

(52) U.S. Cl. 438/617; 438/127

(57) ABSTRACT

A method of encapsulating materials to protect circuit components from the stress of thermal cycling includes applying a first substance to cover Wire bonds on a first layer, applying a second substance to wire bonds on a second layer, and curing the first and second substances by application of heat or radiation to bond the first and second substances together. It is emphasized that this abstract is provided to comply with the rules requiring an abstract which will allow a searcher or other reader to quickly ascertain the subject matter of the technical disclosure. It is submitted with the understanding that it will not be used to interpret or limit the scope or the meaning of the claims.

### CROSS-REFERENCE TO RELATED PATENT APPLICATION

This application claims priority to the U. S. provisional patent application titled “Method of Encapsulating Materials to Reduce Thermal Cycling Stress” and having serial No. 60/646,801, which is hereby incorporated by reference in its entirety as if fully set forth herein.

### FIELD OF THE INVENTION

The present invention generally relates to optical, image projection and multi-component opto-electronic systems. Specifically, the present invention relates to the encapsulation of circuit components of such systems to reduce mechanical stress from thermal cycling.

### BACKGROUND OF THE INVENTION

In optical, imaging and multi-component opto-electronic systems, issues often arise with damage to certain circuit components such as wire bonds resulting from thermal cycling. Stress from thermal cycling causes mechanical stress on these circuit components due to differences in thermal characteristics of materials. When the circuit components are subjected to heating and/or cooling cycles, these differences cause mechanical stress, which when coupled with normal mechanical stresses encountered in handling results in damage to the wire bond. Damage to circuit components results in losses in signal integrity and in optical distortion in optical and imaging systems.

Prior art encapsulation of circuit components uses one material as an encapsulant that is stress-matched to one of the components being assembled. Typically, this encapsulant is a hard or flexible material. However, net thermal cycling stress remains a problem because of additional components that must be encapsulated, and which are made and and/or mounted on different materials.

### SUMMARY OF THE INVENTION

Circuit assemblies having encapsulated wire bonds are implemented in micro displays in systems such as high definition television, liquid crystal on silicon (LCOS) displays, and other high performance optical or image projection systems. Rigid encapsulation is a necessary part of packaging to protect fragile opto-electronic components, such as wire bonds, from the elements and from handling.

Thermal conditions under normal operating cycles often result in degradation of optical performance due to stress-induced distortion or birefringence caused by a thermal coefficient of expansion mismatch among various components and encapsulation materials involved. To reduce this stress, two or more encapsulation substances, at least one of which is a pliable material, are applied to surfaces of wire bonds on joining components to encapsulate them. This protects the components while providing a flexible interface that will reduce the effects of thermo-mechanical stresses.

The foregoing and other aspects of the present invention will be apparent from the following detailed description of the embodiments, which makes reference to the several figures of the drawings as listed below.

### BRIEF DESCRIPTION OF THE DRAWINGS

FIG. 1 is a perspective diagram of components of a circuit assembly according to one embodiment of the present invention;

FIG. 2 is a side diagram of components of a circuit assembly according to the embodiment shown in FIG. 1;

FIG. 3 is a perspective diagram of components of a circuit assembly according to another embodiment of the present invention; and

FIG. 4 is a side diagram of components of a circuit assembly according to the embodiment shown in FIG. 3.

### DETAILED DESCRIPTION OF THE EMBODIMENTS

In the following description of the present invention reference is made to the accompanying drawings which form a part thereof, and in which is shown, by way of illustration, exemplary embodiments illustrating the principles of the present invention and how it may be practiced. It is to be understood that other embodiments may be utilized to practice the present invention and structural and functional changes may be made thereto without departing from the scope of the present invention.

Thermal conditions under normal operating cycles often result in degradation of optical performance due to stress-induced distortion or birefringence caused by a thermal coefficient of expansion mismatch among various components and encapsulation materials involved. The present invention therefore contemplates that two or more encapsulation substances are applied to surfaces of wire bonds on joining components to encapsulate them and protect the components, while providing a flexible interface that will reduce the effects of thermo-mechanical stresses.

Without conventional hard encapsulation of wire bonds, optical, imaging and multi-component opto-electronic systems that consist of two or more components requiring wire bond interconnection suffer from physical distortion, which can translate to optical distortion. In liquid crystal micro-displays, optical distortion occurs when the gap spacing between silicon and glass substrates, separated by some uniformly-sized spacer to define the distance between the two substrates, causes physically distortion relative to each other. This spacing is distorted by physical stress from the mismatched thermal coefficients of expansion of the materials systems. This stress-related optical distortion is typically measured as 1 micron of random distortion, or approximately 2 waves (frequency cycles). By encapsulating the wire bonds and wire connecting loop according the present invention, the optical distortion is reduced to a negligible amount, or less than 0.25 frequency cycles.

On the other hand, when only a soft encapsulant, such as RTV (room temperature vulcanizing) is used to encapsulate the wire bonds of multi-component optoelectronic systems, the reliability of the wire bonds suffers due to the flexibility of the encapsulation. While providing protection against environmental elements such as dust and moisture, flexible encapsulation by itself allows the bonded joints to weaken during thermal cycles by allowing the joints to bend and stretch.

In one embodiment, the present invention provides for the use of two (or more) materials with one material being applied primarily to the side of the wire bonds that attach to the bond pads on a silicon die, and the other material being applied primarily to the side of the wire bonds that attach to the bond pads on a circuit side. In general this circuit is usually a printed circuit which could be made from a flexible polymeric substrate, rigid polymer glass fiber substrate or ceramic substrate.

By incorporating the methods described herein, net stress in thermal cycling of the assembly can be reduced by judicious selection of the two (or more) materials. As opposed to using one material as an encapsulant that may only be stress-matched to one of the components being assembled, this allows for an improved optimization taking into consideration the characteristics of the different materials being bonded together.

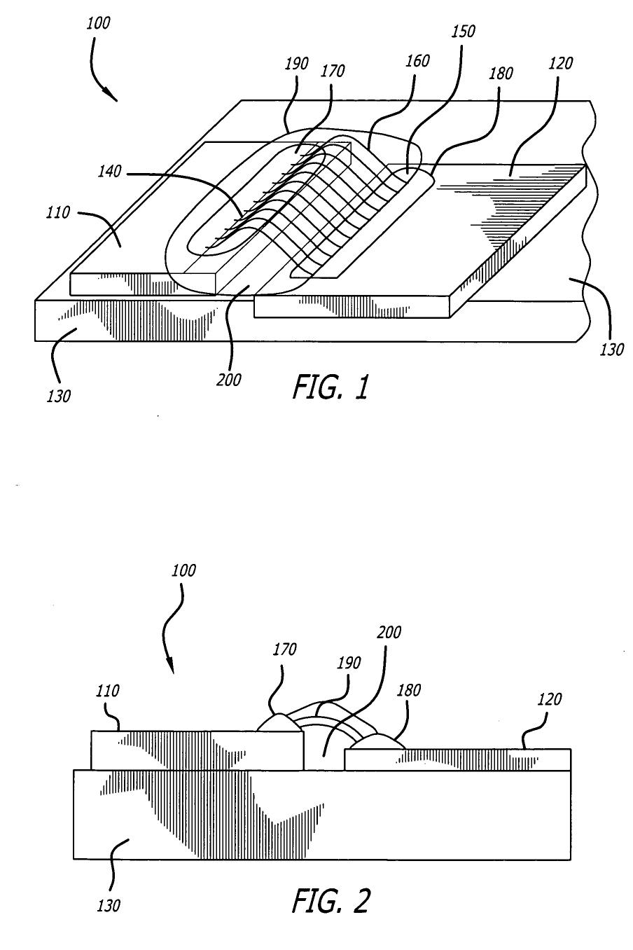

FIG. 1 is a perspective diagram of components of a circuit assembly configured to reduce net stress due to thermal cycling as a result of a mismatch in thermal coefficients of expansion between layers of the circuit assembly and the substrate onto which the first and second layers are mounted, according to one embodiment of the present invention. FIG. 2 is a side perspective diagram of components of a circuit assembly according to the embodiment depicted in FIG. 1.

Referring to FIG. 1 and FIG. 2, a circuit assembly 100 includes a first layer 110 and a second layer 120. The first layer 110 may be a silicon die that is physically separated from the second layer 120. The second layer 120 may be a flex cable that is electrically connected to the silicon die. The first layer 110 and the second layer 120 are mounted on a substrate 130. In one embodiment, the substrate 130 is an aluminum mount. In another embodiment, the substrate 130 is a ceramic mount. In yet another embodiment, the first layer 110 is an integrated circuit chip.

The first layer 110 includes a first plurality of wire bonds 140 which connect the first layer 110 to specific components thereon. The second layer 120 includes a second plurality of wire bonds 150. Between the first plurality of wire bonds 140 and the second plurality of wire bonds 150 is a connecting wire loop 160.

Because of the mismatch in thermal coefficients of expansion between the first layer 110, the second layer 120, and the substrate 130, in operation the circuit assembly 100 suffers from performance degradation due to temperature variations or thermal cycling. Thermal cycling creates mechanical stress on circuit components that often results in circuit components being worn down due to the stress of high and low temperature testing. To reduce this stress, one or more substances are applied to the surfaces of wire bonds on circuit components and to the connecting wire loop 160 to encapsulate them to protect the components from the effects of different applications of temperature.

Accordingly, a circuit assembly 100 includes a first substance 170 encapsulating the first plurality of wire bonds 140 of the first layer 110. The first substance 170 substantially encapsulates the surface areas of the first plurality of wire bonds 140 on the first layer 110. Each wire in the first plurality of wire bonds 140 is entirely encapsulated. The first substance 170 may be hard encapsulant. One example of a commercially available hard encapsulant is an adhesive such as Hysol®. Other examples include UV epoxies such as those manufactured by Norland Products, Inc. Still further examples include two-part mixed epoxies.

The circuit assembly 100 also includes a second substance 180 encapsulating the second plurality of wire bonds 150 on the second layer 120. The second substance 180 substantially encapsulates the surface areas of the second plurality of wire bonds 150 on the second layer 120. As with the first plurality of wire bonds 140, each wire in the second plurality of wire bonds 150 must be entirely encapsulated.

A third substance 190 encapsulates the wire connecting loop 160. The wire connecting loop 160 connects wire bonds of the first plurality of wire bonds 140 and the second plurality of wire bonds 150. On the substrate 130, the first layer 110 and the second layer 120 are separated by a gap 200, within which the wire connecting loop 160 is positioned. The third substance 190 is a flexible bridging material for filling the gap 200 between the first layer 110 and the second layer 120. Additionally, the third substance must entirely encapsulate the wire connecting loop 160. The third substance 190 is a flexible material due to a mismatch between thermal coefficients of expansion between the first layer 110, the second layer 120, and the substrate 150. In one embodiment, the third substance is a flexible silicone encapsulant such as RTV (room temperature vulcanizing) that does not shrink and harden during curing to cause optical distortion. RTV undergoes a process of thermal curing, such that one embodiment of the present invention includes curing silicone adhesives with moisture or a catalyst.

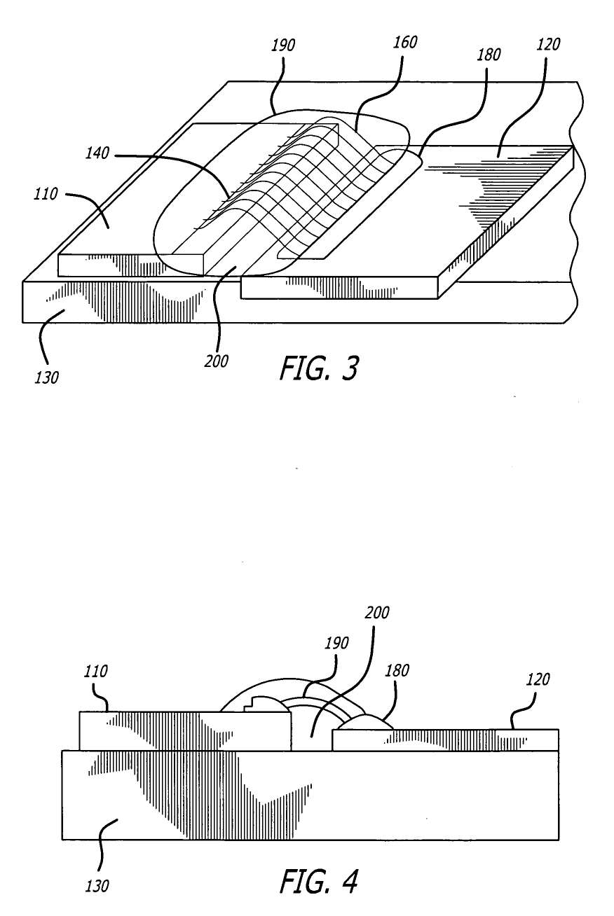

FIG. 3 is a perspective diagram of components of a circuit assembly according to another embodiment of the present invention. FIG. 4 is a side diagram of components of a circuit assembly according to the embodiment depicted in FIG. 3. Referring to FIG. 3 and FIG. 4, a hard encapsulant, shown as the second substance 180, is matched by thermal coefficient of expansion to the bond pad material on the second layer 120. This hard encapsulant therefore is used to encapsulate the second plurality of wire bonds 140 on the second, or flex layer 120. A flexible encapsulant shown as the third substance 190 is used to encapsulate the wire connecting loop 160 in the gap 200 between the silicon layer 110 and the cable 120. In this embodiment, selection of the hard encapsulant used to encapsulate the second plurality of wire bonds 140 on the flex layer 120 and selection of the flexible encapsulant 190 is made so that matches in thermal coefficients of expansion reduce thermal cycling stress so that signal integrity is not compromised.

In the present invention, one method of encapsulating circuit components with a selected substance includes first dispensing the substance onto the circuit component, and then curing the substance by application of heat. In another embodiment, curing can be accomplished by application of radiation to the substance. Additionally, any other method of curing the selected substance to the desired circuit component so that the substance encapsulates the circuit component may also be used.

Therefore, in another embodiment of the present invention, the second plurality of wire bonds 150 of the second or flex layer 120 are encapsulated with a hard encapsulant, or second substance 180. In a next step, the first substance 170 (which also may be a hard encapsulant) is dispensed onto the first or silicon layer 110. The first substance 170 is cured on the first plurality of wire bonds 140. In this embodiment, the first substance 170 may be UV epoxy and the second substance 180 may be Hysol®. However, Hysol® may also be the first substance 170 if dispensed carefully on the first layer 110. Once the wires of the first and second plurality of wire bonds 140 and 150 are entirely encapsulated by the first substance 170 and the second substance 180, these first and second substances 170 and 180 are cured to a hard finish. The third substance 190 is then applied to the gap 200 between the first layer 110 and the second layer 120 and to cover the wire connecting loop 160 of the wire bonds.

During the encapsulation process, dispensing the encapsulant onto the plurality of wire bonds requires precision so as not to further increase mechanical stress from thermal cycling. For example, when the first layer 110 surface is encapsulated, one must ensure that the first substance does not extend over a silicon edge of the first layer 110. One must also ensure that the first substance 170 does not shrink during curing and cause further optical distortion.

As discussed herein, the present invention contemplates that at least the first substance 170 be a hard encapsulant such as Hysol®) or UV curing adhesives manufactured by Norland Products, Inc., for example. These materials meet or exceed aggressive thermal cycling testing, which involves applying 10 cycles of rapid heating and cooling between 0° C. to 90° C. near the liquid crystal clearing temperature. Use of such testing to determine an appropriate encapsulant is effective because the thermal cycle range spans the entire operating temperature range of a typical liquid crystal material used for display applications.

Additionally, when pressure is applied to the flex cable that exceeds what would normally break bonds on RTV encapsulated components, the materials can withstand physical stress without losing electrical connectivity while being heated to 75° C.

It is to be understood that other embodiments may be utilized and structural and functional changes may be made without departing from the scope of the present invention. The foregoing descriptions of embodiments of the invention have been presented for the purposes of illustration and description. It is not intended to be exhaustive or to limit the invention to the precise forms disclosed. Accordingly, many modifications and variations are possible in light of the above teachings. For example, many different materials can be used to encapsulate circuit components according to the present invention to further refine matching between thermal coefficients of expansion. Additionally, multiple materials may be used to encapsulate particular wire bonds on the first or second layer depending on the heat characteristics of those components when connected to particular circuit components. It is therefore intended that the scope of the invention be limited not by this detailed description.

1. A method of reducing thermal cycling stress on a circuit assembly, the method comprising:
applying a first substance to a first layer of the circuit assembly to encapsulate at least one wire bond attached to a first bond pad on the first layer;
applying a second substance to a second layer of the circuit assembly to encapsulate at least one wire bond attached to a second bond pad on the second layer; and
applying a third substance to encapsulate at least one wire bond connection positioned between the first layer and the second layer,
wherein the first substance, the second substance, and the third substance have substantially similar thermal coefficients of expansion.

2. The method of claim 1, wherein the applying a first substance to a first layer of the circuit assembly to encapsulate at least one wire bond attached to a first bond pad on the first layer includes curing the first substance to the at least one wire bond by application of heat.

3. The method of claim 1, wherein the applying a first substance to a first layer of the circuit assembly to encapsulate at least one wire bond attached to a first bond pad on the first layer includes curing the first substance to the at least one wire bond by application of radiation.

4. The method of claim 1, wherein the applying a second substance to a second layer of the circuit assembly to encapsulate at least one wire bond attached to a second bond pad on the second layer includes curing the first substance to the at least one wire bond by application of heat.

5. The method of claim 1, wherein the applying a second substance to a second layer of the circuit assembly to encapsulate at least one wire bond attached to a second bond pad on the second layer includes curing the first substance to the at least one wire bond by application of radiation.

6. The method of claim 1, wherein the applying a third substance to encapsulate at least one wire bond connection positioned between the first layer and the second layer includes curing the first substance to the at least one wire bond by application of heat.

7. The method of claim 1, wherein the applying a third substance to encapsulate at least one wire bond connection positioned between the first layer and the second layer includes curing the first substance to the at least one wire bond by application of radiation.

8. The method of claim 1, wherein the first layer and the second layer are physically separated from each other and are positioned on a substrate.

9. The method of claim 8, wherein the first layer is a silicon layer.

10. The method of claim 9, wherein the first layer is an integrated circuit chip positioned on a substrate.

11. The method of claim 8, wherein the second layer is a cable positioned on the substrate.

12. The method of claim 8, wherein the substrate is an aluminum mount.

13. The method of claim 8, wherein the substrate is a ceramic mount.

14. The method of claim 1, wherein the one least one wire bond connection is positioned in a gap between the first layer and second layer.

15. The method of claim 8, wherein the first substance, the second substance and the third substance are polymers.

16. The method of claim 15, further comprising matching a thermal coefficient of expansion of the first substance to a thermal coefficient of expansion of silicon.

17. The method of claim 15, further comprising matching a thermal coefficient of expansion of the second substance to a thermal coefficient expansion of a pad material on flex.

18. The method of claim 15, wherein the third substance is a flexible material.

19. The method of claim 18, wherein the third substance is silicone RTV.

20. A circuit assembly comprising:
a first layer having at least one circuit component encapsulated with a first substance;
a second layer having at least one circuit component encapsulated with a second substance; and
a bridging material substantially encapsulating at least one connective component positioned within a gap between the encapsulated first layer and the encapsulated second layer,
wherein the first substance, the second substance, and the bridging material have substantially similar thermal coefficients of expansion.

21. The circuit assembly of claim 20, further comprising a substrate, the first layer and the second layer being physically separated from each other and positioned on the substrate.

22. The circuit assembly of claim 21, wherein the first layer is a silicon layer.

23. The circuit assembly of claim 21, wherein the first layer is an integrated circuit chip positioned on a substrate.

24. The method of claim 21, wherein the second layer is a cable positioned on the substrate.

25. The circuit assembly of claim 20, wherein the at least one wire bond connection is positioned in a gap between the first layer and second layer.

26. The circuit assembly of claim 20, wherein the first substance, the second substance and the third substance are polymers.

27. The circuit assembly of claim 26, wherein the first substance is a hard encapsulant having a thermal coefficient of expansion matched to a thermal coefficient of expansion of silicon.

28. The circuit assembly of claim 26, wherein the second substance is a hard encapsulant having a thermal coefficient of expansion matched to a thermal coefficient expansion of a pad material on flex.

29. The circuit assembly of claim 26, wherein the third substance is a flexible material.

30. The circuit assembly of claim 29, wherein the third substance is silicone RTV.

31. The circuit assembly of claim 21, wherein the circuit assembly is a printed circuit mounted on a flexible polymeric substrate.

32. The circuit assembly of claim 21, wherein the circuit assembly is a printed circuit mounted on a rigid polymer glass fiber substrate.

33. The circuit assembly of claim 21, wherein the circuit assembly is a printed circuit mounted on a rigid polymer ceramic substrate.

34. A method of reducing thermal cycling stress in a circuit assembly, comprising:
dispensing a first encapsulant on a flex layer of a circuit assembly;
dispensing a second encapsulant on a silicon layer of the circuit assembly;
curing the second encapsulant onto a plurality of wire bonds on the silicon layer;
curing the first encapsulant onto the plurality of wire bonds on the first layer to a hard finish; and
applying a third encapsulant to a wire loop connecting the plurality of wire bonds on the flex layer with the plurality of wire bonds on the silicon layer, the wire loop positioned in an area between the silicon layer and the flex layer,
wherein the first encapsulant is selected for having a substantially similar coefficient of thermal expansion as the first layer, and the second encapsulant is selected for having a substantially similar coefficient of thermal expansion as the second layer.

35. The method of claim 34, wherein the curing the second encapsulant onto a plurality of wire bonds on the silicon layer further comprises applying heat to the second substance.

36. The method of claim 34, wherein the curing the second encapsulant onto a plurality of wire bonds on the silicon layer further comprises applying radiation to the second substance.

37. The method of claim 34, wherein the curing the first encapsulant onto the plurality of wire bonds on the first layer to a hard finish further comprises applying heat to the first substance.

38. The method of claim 34, wherein the curing the first encapsulant onto the plurality of wire bonds on the first layer to a hard finish further comprises applying radiation to the first substance.

39. The method of claim 34, further comprising curing the third substance onto the wire loop by applying heat to the third substance.

40. The method of claim 34, further comprising curing the third substance onto the wire loop by applying radiation to the third substance.

41. The method of claim 34, wherein the third encapsulant is a flexible material.

42. The method of claim 41, wherein the third encapsulant is made of a flexible material to due to a coefficient mismatch between the first layer, the second layer, and the substrate.

43. The method of claim 42, wherein the flexible material is silicone RTV.

44. The method of claim 34, wherein the curing the second encapsulant onto a plurality of wire bonds on the silicon layer includes entirely encapsulating the plurality of wire bonds on the silicon layer.

45. The method of claim 44, wherein the curing the first encapsulant onto the plurality of wire bonds on the first layer to a hard finish includes entirely encapsulating the plurality of wire bonds on the flex layer.

46. A method of manufacturing a circuit assembly, comprising:
dispensing a first substance to encapsulate a plurality of circuit components on a flex layer positioned on a substrate;
curing the first substance onto the plurality of components on the flex layer so that the plurality of components are entirely encapsulated; and
encapsulating, with a second substance, a connective component used to connect circuit components positioned on the flex layer with circuit components on a silicon layer on the substrate, wherein thermal coefficients of expansion of the first substance and the second substance are matched with the flex layer and with silicon, respectively, so that mechanical stress on the circuit assembly from thermal cycling is reduced.

47. The method of claim 46, wherein the curing the first substance onto the plurality of components on the flex layer so that the plurality of components are entirely encapsulated further comprises applying heat to the first substance.

48. The method of claim 46, wherein the curing the first substance onto the plurality of components on the flex layer so that the plurality of components are entirely encapsulated further comprises applying radiation to the first substance.

49. The method of claim 46, wherein the encapsulating, with a second substance, a connective component used to connect circuit components positioned on the flex layer with circuit components on a silicon layer on the substrate further includes applying heat to the second substance.

50. The method of claim 46, wherein the encapsulating, with a second substance, a connective component used to connect circuit components positioned on the flex layer with circuit components on a silicon layer on the substrate further includes applying radiation to the second substance.

51. The method of claim 46, wherein the first substance is hard encapsulant.

52. The method of claim 46, wherein the second substance is a flexible material.

53. The method of claim 52, wherein the flexible material is silicone RTV.

55. The method of claim 46, wherein the encapsulating, with a second substance, a connective component used to connect circuit components positioned on the flexible layer with circuit components on a silicon layer on the substrate includes entirely encapsulating an area between the flex layer and silicon layer.

55. The method of claim 46, further comprising separating the flex layer and the silicon layer from each other when positioned on the substrate.

57. The method of claim 55, wherein the silicon layer is an integrated circuit chip positioned on the substrate.

58. The method of claim 56, wherein the flex layer is a cable positioned on the substrate.
